(19) United States
(12) Patent Application Publication
(10) Pub. No.: US 2013/0271927 A1
(43) Pub. Date: Oct. 17, 2013

(54) Mainboard having a reverse current blocking arrangement

(71) Applicant: Chih Ting Lu, New Taipei (TW)

(72) Inventor: Chih Ting Lu, New Taipei (TW)

(21) Appl. No.: 13/443,892

(22) Filed: Apr. 11, 2012

(51) Int. Cl. H05K 1/18

(52) U.S. Cl. 361/748

(57) ABSTRACT

A mainboard is provided with a plurality of USB connectors; a switching circuit; a current limiting circuit electrically connected to the switching circuit; a power loop for supplying electrical power to the switching circuit, the current limiting circuit, and the USB connectors; and a control chip. The control chip is programmed to enable the switching circuit so that current is blocked flowing from at least one of the USB connectors to the switching circuit via the current limiting circuit when the mainboard is powering on.

### BACKGROUND OF THE INVENTION

1. Field of the Invention

The invention relates to mainboards and more particularly to a mainboard having a switching circuit which can be disabled by programming so that current is blocked flowing from an attached Universal Serial Bus (USB) device to the switching circuit via a current limiting circuit when the mainboard is powering on.

2. Description of Related Art

Conventionally, a mainboard comprises a Set of USB connectors having a plurality of USB ports, such as an USB connector and three USB connectors. Electrical power may flow from a USB device attached to the USB connector to the mainboard, i.e., reverse current flow. However, the reverse current may interfere with a normal operation (e.g., Power-On Self-Test (POST)) of the mainboard when a personal computer (PC) incorporating the mainboard is powering on (i.e., booting). Thus, the need for preventing a reverse current from flowing into the mainboard during POST exists.

### SUMMARY OF THE INVENTION

It is therefore one object of the invention to provide a mainboard comprising a plurality of USB connectors; a switching circuit; a current limiting circuit electrically connected to the switching circuit; a power loop for supplying electrical power to the switching circuit, the current limiting circuit, and the USB connectors; and a control chip; wherein the control chip is programmed to enable the switching circuit so that current is blocked flowing from at least one of the USB connectors to the switching circuit via the current limiting circuit when the mainboard is powering on.

The above and other objects, features and advantages of the invention will become apparent from the following detailed description taken with the accompanying drawings.

### BRIEF DESCRIPTION OF THE DRAWINGS

FIG. 1 is a block diagram of a mainboard according to the invention.

### DETAILED DESCRIPTION OF THE INVENTION

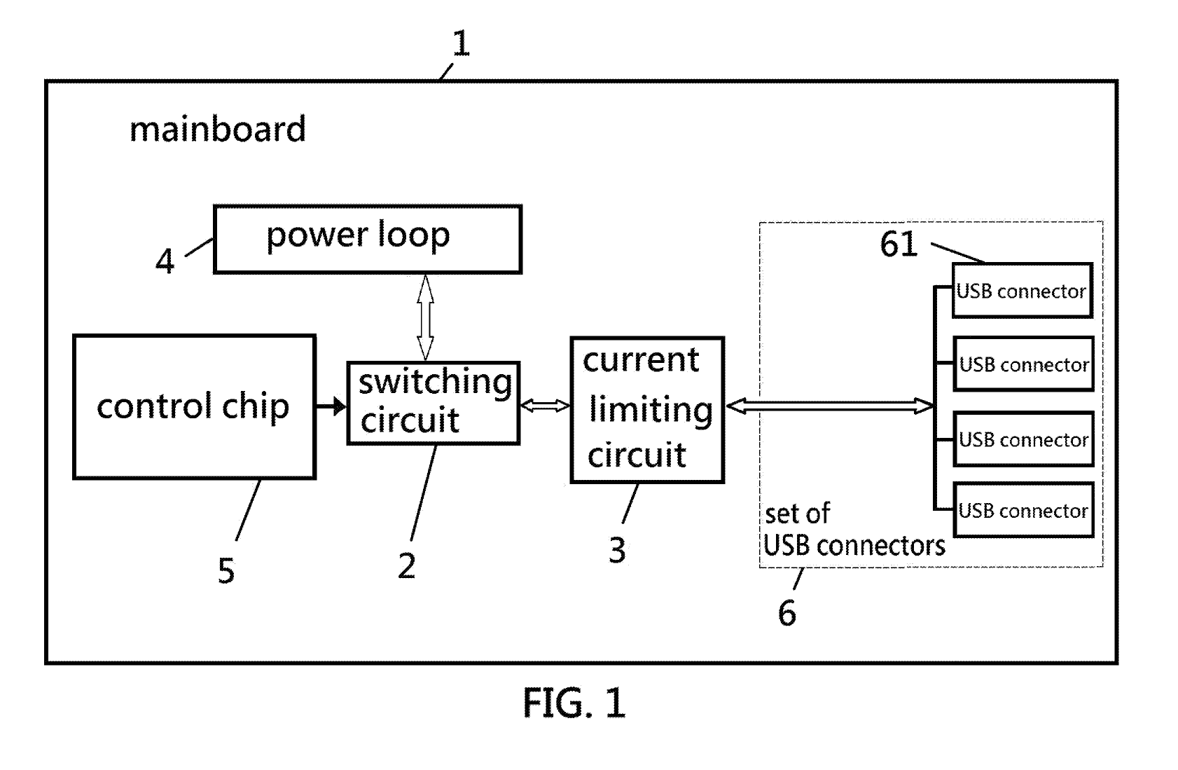

Referring to FIG. 1, a mainboard 1 in accordance with the invention comprises the following components as discussed in detail below.

A set of USB connectors 6 comprises a plurality of (e.g., four) USB connectors 61. A switching circuit 2 and a current limiting circuit 3 are electrically interconnected. The switching circuit 2 is an MOS (metal oxide semiconductor) type switching circuit. The current limiting circuit 3 sets current supplied to any USB device (not shown) attached to one of the USB connectors 61 to a safe predetermined value. A power loop 4 receives electrical power from a power supply unit (not shown) and supplies same to the switching circuit 2, the current limiting circuit 3, the set of USB connectors 6, and other components of the mainboard. A control chip 5 has a plurality of interfaces and uses, for example, an LPC (Low Pin Count) bus for communicating with a CPU (Central Processing Unit).

It is envisaged by the invention that the control chip 5 can be programmed to enable the switching circuit 2 so as to block current flowing from any attached USB device to the switching circuit 2 via the USB connector 61 and the current limiting circuit 3 during POST (i.e., a PC incorporating the mainboard is powering on). As a result, a successful power-on of the PC can be achieved.

While the invention has been described in terms of preferred embodiments, those skilled in the art will recognize that the invention can be practiced with modifications within the spirit and scope of the appended claims.

What is claimed is:

1. A mainboard comprising:
a plurality of USB connectors;
a switching circuit;
a current limiting circuit electrically connected to the switching circuit;
a power loop for supplying electrical power to the switching circuit, the current limiting circuit, and the USB connectors; and
a control chip;
wherein the control chip is programmed to enable the switching circuit so that current is blocked flowing from at least one of the USB connectors to the switching circuit via the current limiting circuit when the mainboard is powering on.
